(19) United States
(12) Patent Application Publication
(10) Pub. No.: US 2007/0114575 A1
(43) Pub. Date: May 24, 2007

(54) Oil immersed transistor

(76) Inventor: Yoshioki Tomoyasu, Fujisawa-shi (JP)

Correspondence Address: Yoshioki Tomoyasu, 21-22, Mirokuji 3-chome, Fujisawa-shi, Kanagawa-ken, 251-0016, JP

(21) Appl. No.: 11/284,360

(22) Filed: Nov. 22, 2005

(51) Int. Cl. H01L 29/80

(52) U.S. Cl. 257/265

(57) ABSTRACT

The invention is directed to develop for the higher performance of the transistor as well as the semi-conductor by means of immersing into the high voltage of oil solution to be circulated in and out of the housing to cool down the heat of the conductor and to lower the dielectric constant to prevent from the electric leakage and the heavier electric consumption.

### FIELD OF THE INVENTION

The present invention is generally directed to developing for the transistor as well as the semi-conductor to solve the problems faced with further performance required for the various application, specifically saving electric consumption and lowering dielectric constant of the insulating film so that the electric leakage may be diminished in suppressing heat to be set up in operation involved.

### BACKGROUND OF THE INVENTION

1. Field of the Invention

This invention relates to the technology to solve the problem of transistors faced with heavier electric consumption and considerable dielectric constant of the film applied on the conductor causing the electric leakage.

2. Description of the Prior Art

The prior art of the transistor as well as the semi-conductor depend on applying thin film on the surface of the conductor in wafer with considerable dielectric constant which is not adequate for the higher performance and less electric consumption required for further development for the computer.

### SAMMARY OF THE INVENTION

The present invention is generally directed to develop for a high performance of the transistor as well as the semi-conductor by means of immersing in oil solution with high voltage which is circulated mechanically in and out of the housing, thus enabling to lower the dielectric constant to prevent from possible electric leakage caused by insulating film and diminish heavy electric consumption.

### BRIEF DESCRIPTION OF THE DRAWINGS

FIG. 1: The flat view of a system of this invention as an example of the invention

### DETAILED DESCRIPTION OF THE INVENTION

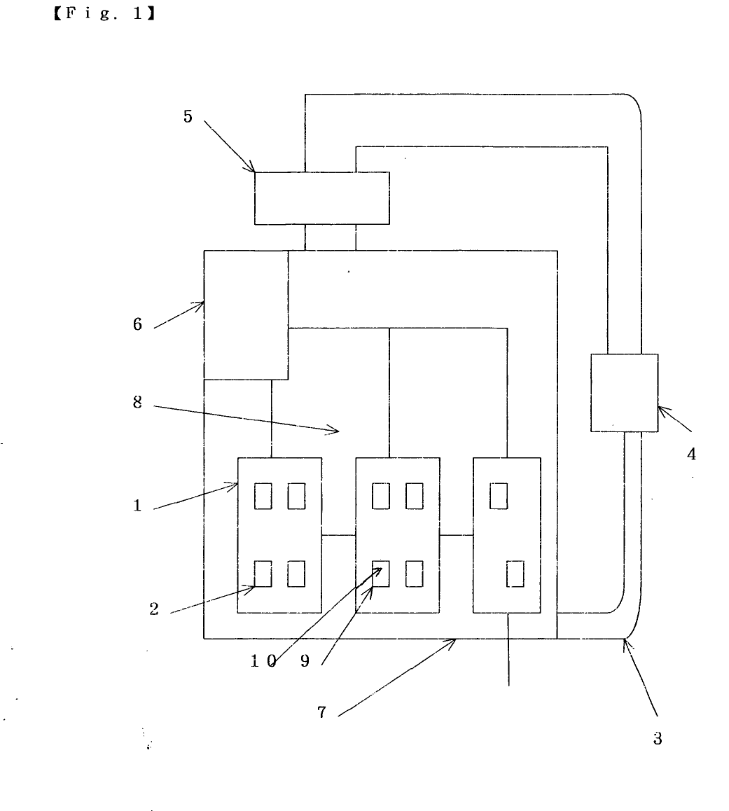

As shown FIG. 1, the present invention is related to the oil (8) immersed transistors (2) as well as semi-conductors (1) to replace with films applied to the integrated circuit (10) to diminish the dielectric constant and to cool down heat, thus accelerating the speed of carrier flowing through electric current transmitted from the source (6). The oil (8) immersing transistors (2) as well as conductors (1) is mechanically driven to circulate in and outside housing (7) equipped with a hose (3) to flow through a cooler (4), thus enabling to reduce electric consumption and accelerate the speed of the carrier therein. Furthermore, the oil solution (8) as hereinbefore set forth is provided with high voltage produced by a condenser (5) with view to attracting carriers by dint of static electricity entailed, thus resulting at accelerating flow of carrier to cool down the heat set up for the conductor of the integrated circuit (10) as well as wafer (9) and decreasing electric consumption involved.

One of the remarkable features of this invention is to make break through on the problem of the new materials for the wafer (9) of the transistor (2) as well as the semi-conductor (1) such as silicon for insulating capacity to be replaced with other material available for more suitable for further micro process for complicated design on the integral circuit allowing for larger capacity

The present invention enables to solve the problem to apply oil (8) of which dielectric constant is lower than that of the silicon wafer (9) and to accelerate the flowing speed of the carrier resulting at lower electric consumption and so being needless to replace the silicon wafer (9) with other material for the capacity to the level required. Especially in case with the application of the high voltage oil (8) for the transistor (2) as well as the semi-conductor (1), the carrier in micro processed integral circuit (10) is apt to be attracted by dint of static electricity to be accelerated to lower the heat and the flowing speed to the level required in accordance with the theory of the condenser.

1. The design of the integrated circuit of a transistor (1) immersed in oil solution (8) to replace insulating film coated on the surface of conductors in wafer thereof, thus lowering the dielectric constant to prevent the film from possible electric leakage and accelerating the speed of the flow of carrier in operation to suppress the overheat and diminish owing to the heavy electric consumption.

2. As hereinbefore set forth in clause (1), the oil solution (8) immersing the integrated circuits as well as semi-conductors are designed to be circulated in and out of the case to cool down the heat of the transistors as well as the semi-conductors, thus keeping the dielectric constant at low level.

3. As hereinbefore set force in clause (1) and clause (2), the oil solution which is designed to be circulated in and out of the case is kept in high voltage in order to accelerate the flow of the carrier by dint of attraction of the static induction to prevent from setting up possible overheat as well as causing electric leakage.
